(19) United States
(12) Patent Application Publication
(10) Pub. No.: US 2017/0099036 A1
(43) Pub. Date: Apr. 6, 2017

(54) RF FRONT END ARCHITECTURES

(71) Applicant: FERFICS LIMITED, Cork (IE)

(72) Inventor: EUGENE HEANEY, ROCHESTOWN (IE)

(21) Appl. No.: 15/286,060

(22) Filed: Oct. 5, 2016

Related U.S. Application Data
(60) Provisional application No. 62/237,653, filed on Oct. 6, 2015.

(51) Int. Cl. H03F 1/26; H03F 3/193; H03F 3/217; H03F 1/56

(52) U.S. Cl. CPC H03F 1/26; H03F 1/565; H03F 3/193; H03F 3/2171; H03F 2200/294; H03F 2200/451; H03F 2200/222; H03F 2200/387

(57) ABSTRACT

An RF front end circuit is described. The RF front end circuit comprises a plurality of amplifiers defining multiple amplification branches. A plurality of input nodes are provided which are associated with one or more amplification branches. A plurality of output matching networks are provided which are associated with one or more amplication branches. The amplifiers are selectively controllable such that one or more amplifiers associated with one or more active input nodes are activated while other amplifiers associated with the one or more active input nodes are deactived.

### RELATED APPLICATIONS

The present invention claims priority from U.S. Provisional Application Ser. No. 62/237653, filed 6 Oct. 2015, the entirety of which is incorporated herein by reference.

### FIELD OF THE INVENTION

The present disclosure relates to radio frequency front end architectures. In particular but not exclusively, the present disclosure relates to RF front end circuits having a reduced noise figure by eliminating the requirement for switches connected to the inputs to low noise amplifiers.

### BACKGROUND

RF front end architectures containing LNAs are key building block in the front end of wireless systems and find many uses in applications such as mobile phones and wireless LANs. A low-noise amplifier is used to increase the dynamic range of a receiver. The LNA is used to provide amplification when the signal level is weak. The output of the LNA provides the signal to the receiver that is of sufficient amplitude to meet the required system sensitivity.

Performance metrics such as noise figure, gain, linearity, input and output return loss are critical in RF LNA design. Typically the signals that are connected to the input ports of the RF Switch LNA contain frequencies that fall within specific bands. Each of the input ports carries signals that fall within different frequency bands. Advances in carrier aggregation introduces new requirements on RF front end circuits that require one or more inputs to be amplified and routed to one or more output paths for subsequent processing through the receive chain.

There is therefore a need to provide an RF front end circuit that addresses at least some of the drawbacks of the prior art.

### SUMMARY

These and other problems are addressed by providing an RF front end circuit circuits having a reduced noise figure by eliminating the requirement for switches connected to the inputs of the low noise amplifiers.

The present disclosure relates to an RF front end circuit comprising
a plurality of amplifiers defining multiple amplification branches;
a plurality of input nodes being associated with one or more amplification branches;
a plurality of output matching networks being associated with one or more amplication branches;
wherein the amplifiers are selectively controllable such that one or more amplifiers associated with one or more active input nodes are activated while other amplifiers associated with the one or more active input nodes are deactived.

In one aspect, by selectively controlling the amplifiers to be active or inactive as required eliminates the need for switches being connected to the inputs of the amplifiers thereby avoiding insertion losses associated with switches contributing to the noise figure of the amplification branches.

In another aspect, multiple amplifiers are activated that are associated with different active input nodes while other amplifiers associated with the different active input nodes are deactived.

In a further aspect, multiple amplifiers are activated simultaneously that are associated with different active input nodes while other amplifiers associated with the different active input nodes are deactived simultaneously.

In an exemplary embodiment, a control circuit is provided for selectively activating the amplifiers.

In another aspect, a plurality of splitters are provided each associated with a corresponding output matching network for splitting the signals from the respective output matching networks into split output signals.

In one aspect, an output switching network is provided for selectively switching the split output signals to selected output nodes.

In an exemplary aspect, each input matching network comprises one or more frequency dependent components.

In a further aspect, each input matching networks comprises one or more inductive elements.

In one aspect, each amplifier comprises an input DC blocking capacitor. Advantageously, each input DC blocking capacitor is operably coupled to a gate of a first transistor.

In a further aspect, a first DC bias voltage source is operably coupled to the gate of the first transistor via a resistive load.

In another aspect, a cascode transistor is operably coupled to the first transistor which together form an amplification stage.

In one aspect, a second DC bias voltage source is operably coupled to the gate of the cascode transistor.

In a further aspect, the cascode transistor is operably coupled to an inductor.

In an exemplary aspect, an output DC blocking capacitor is operably coupled to the two or more amplifier networks.

In one aspect, each amplification branch comprises a degeneration inductor operably coupled to the first transistor.

In an exemplary aspect, the low noise amplifier has a Noise Figure of less than 1 dB.

In another aspect, the low noise amplifier has a Noise Figure of less than 2 dB.

In one aspect, the low noise amplifier is configured to provide a gain of between 10 dB and 20 dB within its frequency range of operation.

The present disclosure also relates to a semiconductor substrate having an RF front end circuit fabricated thereon; wherein the RF front end circuit comprises:
a plurality of amplifiers defining multiple amplification branches;
a plurality of input nodes being associated with one or more amplification branches;
a plurality of output matching networks being associated with one or more amplication branches;
wherein the amplifiers are selectively controllable such that one or more amplifiers associated with one or more active input nodes are activated while other amplifiers associated with the one or more active input nodes are deactived.

Additionally, the present treaching relates to a method of fabricating an RF front end circuit, the method comprising:
providing a plurality of amplifiers on a substrate defining multiple amplification branches;
providing a plurality of input nodes being associated with one or more amplification branches;
providing a plurality of output matching networks on the substrate being associated with one or more amplication branches;
wherein the amplifiers are selectively controllable such that one or more amplifiers associated with one or more active input nodes are activated while other amplifiers associated with the one or more active input nodes are deactived.

These and other features will be better understood with reference to the following Figures which are provided to assist in an understanding of the present teaching.

### BRIEF DESCRIPTION OF THE DRAWINGS

FIG. 1 is a circuit diagram of a prior art RF front end architecture.

FIG. 2 is a block diagram of a prior art RF front end architecture.

FIG. 3 is a circuit diagram of an RF front end circuit in accordance with the present teaching.

FIG. 4 is a circuit diagram of another RF front end circuit which is also in accordance with the present teaching.

FIG. 5 is a circuit diagram of a detail of the circuits of FIGS. 3 and 4.

FIG. 6 is a circuit diagram of a detail of the circuits of FIGS. 3 and 4.

FIG. 7 is a circuit diagram of a detail of the circuits of FIGS. 3 and 4.

FIG. 8 is a schematic diagram of an exemplary RF circuit which incorporates the RF front end architecture of FIG. 4.

FIG. 9 is a cross section of a silicon-on-insulator substrate on which the circuit of FIG. 8 is fabricated thereon

### DETAILED DESCRIPTION OF THE DRAWINGS

The present teaching will now be described with reference to some exemplary RF front end architectures. It will be understood that the exemplary RF front end architectures are provided to assist in an understanding of the present teaching and are not to be construed as limiting in any fashion. Furthermore, circuit elements or components that are described with reference to any one Figure may be interchanged with those of other Figures or other equivalent circuit elements without departing from the spirit of the present teaching.

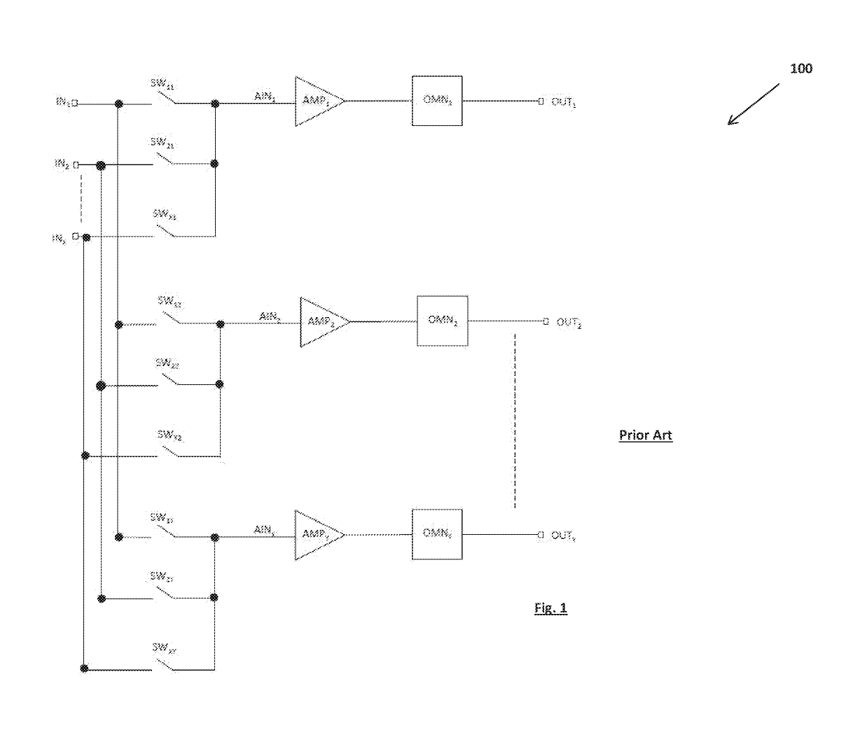

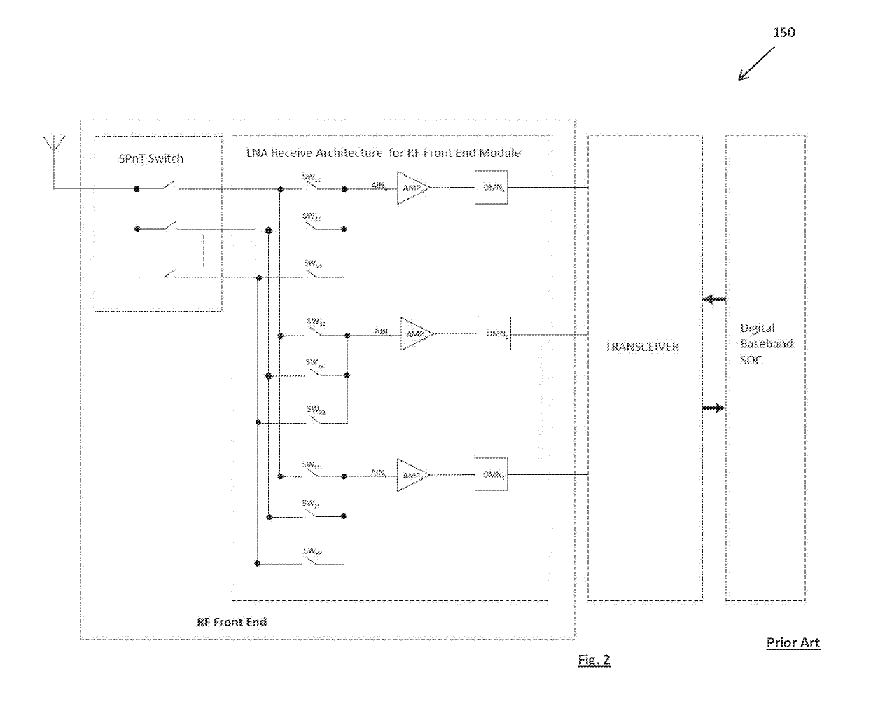

In advance of describing a radio frequency (RF) front end architecture in accordance with the present teaching, an exemplary prior art front end architure is first described with reference to FIGS. 1 to 2. FIG. 1 illustrates a prior art low noise amplifier (LNA) receive architecture 100 that is typically used in an RF front end of a wireless system 150 such as that shown in FIG. 2. This typical LNA receive architecture 100 includes three input ports, IN₁, IN₂, IN_{X} and three output ports, OUT₁, OUT₂, OUT_{Y}. Each output port has an associated low noise amplifier (LNA), and an output matching network, OMN. The OMN is required to tune the output of the LNA to operate optimally over a particular band of frequencies. The input ports, AIN₁, AIN₂, AIN₃, of each of the three LNAs, AMP₁, AMP₂, AMP₃, respectively is connected to the pole of a SP3T switch so that any of the three input ports IN₁, IN₂, IN_{X} can be selected as the input to the amplification stage. In this way any of the three input signals can be selected to be amplified and provide the output on any of the three output ports. For example if switch arms SW₁₁, SW₂₂ and SW_{2Y} are selected to be in a low insertion loss on-state and all other switch arms are selected to be in a high isolation off-state then the input port IN₁ is selected as input AIN₁ to AMP₁ and IN₂ is selected as input AIN₂ and AIN₃, on both AMP₂ and AMP₃. If all three LNAs are set to be in the active high gain state in this condition then an amplified version of the signal IN₁ is output at OUT₁ and an amplified version of the input signal IN₂ is output at both OUT₂ and OUT_{Y}.

One major drawback to the arrangement of FIG. 1 is the requirement to include switches at input side of each LNA to select the signal that is to be amplified. The insertion loss of the RF switch will directly add to the noise figure, NF, of the LNA so the resultant noise figure for the path is significantly higher.

NF_{SYS}(dB)=NF_{LNA}(dB)+IL_{SW}(dB), Equation 1

Where NF_{SYS}(dB), is the noise figure of a system in dB,
NF_{LNA}(dB), is the noise figure of an LNA in dB and
IL_{SW}(dB), is the insertion loss of a switch in dB.

Typically targets for the noise figure of a LNA system is <1 dB and the typical insertion loss for a switch is 0.5 dB. Clearly from this, the insertion loss of the switch uses up a significant portion of the noise figure allowance requiring a much lower noise figure from the LNA. In this case the noise figure for the LNA should be less than 0.5 dB in order to meet the system target. In real systems this level of noise figure may not be possible to achieve without requiring higher power consumption in the LNA than would not be acceptable in wireless systems that are typically portable, battery operated and constrained to a low level of power consumption. If higher power consumption cannot be accepted then the system 150 will have a higher noise figure which will reduce the sensitivity of the overall receive system thereby reducing both the range and the information throughput of receive system.

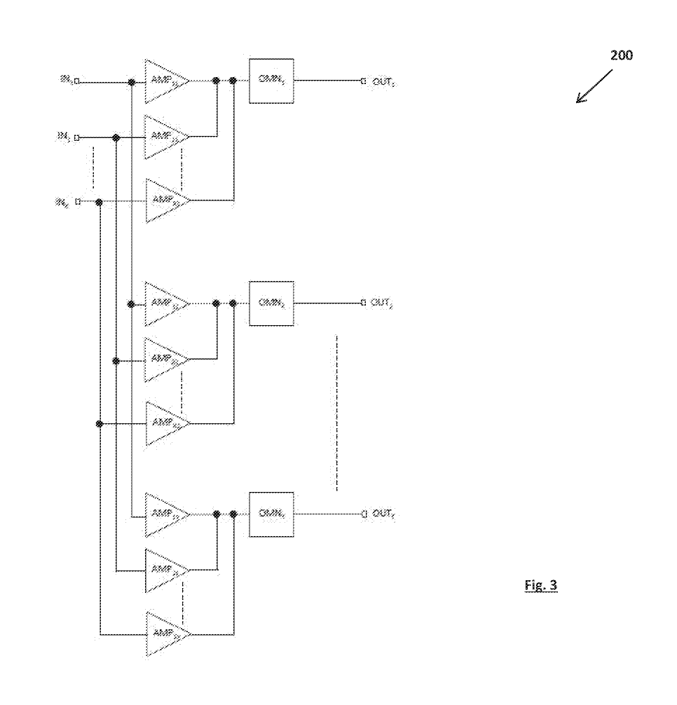

FIG. 3 shows an exemplary RF front end circuit 200 in accordance with the present teaching. RF front end is a commonly understood term for circuits and functions located between the antenna and transceiver of a wireless system. The RF front end circuit 200 addresses the problem described with reference to the prior art architecture 100 by creating an RF front end circuit containing low noise amplifiers (LNAs) where one or more inputs may be amplified and routed to one or more outputs without requiring a switch at the input to each of the LNA stages.

NF_{SYS}(dB)=NF_{LNA}(dB) Equation 2

Where NF_{SYS}(dB), is the noise figure of a system in dB, and
NF_{LNA}(dB), is the noise figure of an LNA in dB.

The noise figure achieved by the RF front end circuit 200 is lower than the noise figure of the front end circuit 100 by eliminating the the contribution of the insertion loss of the switch. This allows receive systems to be implemented that have lower power consumption, lower area and better sensitivity than previously possible.

In the exemplary front end circuit 200 each input IN₁ to IN_{X} is connected to multiple amplifier inputs in the following way; IN₁ connects to the inputs of AMP₁₁, AMP₁₂ and up to AMP_{1Y}. IN₂ connects to the inputs of AMP₂₁, AMP₂₂ and up to AMP_{2Y}, and so on. This can be generalized to IN_{X} connects to the inputs of AMP_{X1}, AMP_{X2} and up to AMP_{XY}. The amplifier may consist of a network of transistors that amplify the signal at the input.

The outputs of the amplifiers AMP_{1Y}, AMP_{2Y} up to AMP_{XY} are connected together to a common node and this common node is connected to an output matching network (OMN_{Y}) and this OMN_{Y} network is connected to OUT_{Y}. The OMN can consist of any network and typically it is used to transform the output impedance of the amplifiers to the impedance of the load at OUT_{Y}.

In the front end circuit 200 AMP₁₁, AMP₂₁ up to AMP_{X1} is connected to OMN₁ which is connected to Output₁, and for example OMN₁ can consist of a shunt Inductor and series capacitor. The RF front end circuit 200 may operate as follows; if IN_{X} needs to be amplified and switched to OUT_{Y} then AMP_{XY} is turned on and all other amplifiers connected to OMN_{Y} are turned off. Also all amplifiers connected to IN_{X} (AMP_{X1} to AMP_{XY} except AMP_{XY}) are turned off. In this way the signal at IN_{X} is amplified through AMP_{XY} connected to OMN_{Y} and then connected to OUT_{Y}. The front end circuit 200 allows the simultaneous connection of other inputs to other outputs. So for example another input IN₁ could simultaneously be connected to AMP₁₂ which would be connected to OMN₂ and then connected to Out₂. Then AMP₁₁ to AMP_{1X} are all turned off except AMP₁₂, and AMP₁₁ to AMP_{1Y} are also turned off except AMP₁₂. In this way IN₁ is amplified and switched to OUT₂ and simultaneously IN_{X} is amplified and switched to OUT_{Y}.

It will be appreciated by those skilled in the art that the RF front end circuit 200 includes a plurality of amplifiers defining multiple amplification branches. A plurality of input nodes are associated with one or more amplification branches. A plurality of output matching networks are associated with the one or more amplication branches. The amplifiers are selectively controllable such that one or more amplifiers associated with one or more active input nodes are activated while other amplifiers associated with the one or more active input nodes are deactived.

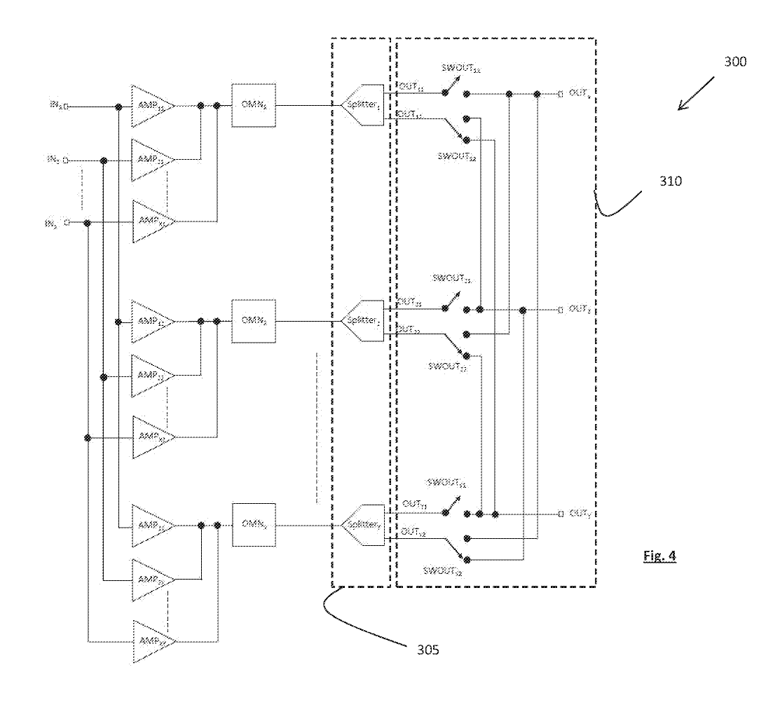

FIG. 4 illustrates another front end circuit 300 which is also in accordance with the present teaching. The front end circuit 300 is similar to the front circuit 200 but includes splitters 305 and and an output switching network 310. The front circuit 300 similarly to the RF front end circuit 200 provides an RF front end architecture containing low noise amplifiers (LNAs) where one or more inputs may be amplified and routed to one or more outputs without requiring a switch at the input to each of the LNA stages.

In the front end circuit 200 any one input could at any one time be connected to one or more outputs. If there is only one input that is required to be amplified and output on more than one output port then an amplifier and output matching network stage is still required for each output port. The front end circuit 300 in addition allows to connect one input to multiple outputs simultaneously. In the circuit 300 each input IN₁ to IN_{X} is connected to multiple amplifier inputs in the following way; IN₁ connects to the inputs of AMP₁₁, AMP₁₂ and up to AMP_{1Y}. IN₂ connects to the inputs of AMP₂₁, AMP₂₂ and up to AMP_{2Y} and so on. This may be generalized to IN_{X} connects to the inputs of AMP_{X1}, AMP_{X2} and up to AMP_{XY}. If there is only one input that is required to be amplified and output on more than one output port then only one amplifier and one output matching network stage is required.

The amplifiers may consist of a network of transistors that amplify the signal at the input. The outputs of the amplifiers AMP_{1Y}, AMP_{2Y} up to AMP_{XY} are connected together to a common node and this node is connected to an output matching network (OMN_{Y}). OMN_{Y} is then connected to an N-way splitter, where N is the maximum number of output ports that can simultaneously be connected to an input. In the diagram for simplicity it is drawn as a two way splitter, i.e. in this system one input can at most be connected simultaneously to at most two outputs. It is not intended to limit the present teaching to a two way splitter as any desired multi-way splitter may be used as would be appreciated by those skilled in the art. The primary output of the splitter is connected through a single pole single throw switch to OUT_{Y}. There are N−1 secondary outputs of the splitter and each one of these is connected to a single pole (Y−1) throw switch SP(Y−1)T switch; i.e. each SP(Y−1)T outputs connects to all other output ports except the output port that the primary output of the splitter is connected to through an SPST switch.

The OMN and the splitter are drawn as separate networks, but these networks may be combined into a single network which implements the output matching and the splitting simultaneously. An example of this would be a transformer network.

The RF front end circuit 300 operates as follows; if IN_{X} needs to be amplified and switched to OUT then AMP_{XY} is turned on and all other amplifiers connected to OMN_{Y} are turned off. Also all amplifiers connected IN_{X} (AMP_{X1} to AMP_{XY} except AMP_{XY}) are turned off. In this way the signal at IN_{X} is amplified through AMP_{XY} connected to OMN_{Y} and then connected to Splitter_{Y}. The switch at the primary output of the splitter is turned on and the signal in this way is connected to OUT_{Y}. All other switches connected to OUT_{Y} are turned off. If in this example it is desired to amplify and route the signal only to OUT_{Y} then the switch at the secondary output of Splitter_{Y} is turned off.

If however it is desired to also amplify and route the signal at IN_{X} to another output simultaneously, say for example Out₂, then in addition to the above description the switch at the secondary output of Splitter_{Y} is turned on and switched to OUT₂. All other switches connected to OUT₂.

It should be noted that the switches of the switching network 310 are positioned at the output side of the splitters 305 and do not contribute to system noise figure. These switches are positioned at output side of the LNA so the contribution of their insertion loss to system noise figure is reduced by the gain of the LNA and is therefore negligible.

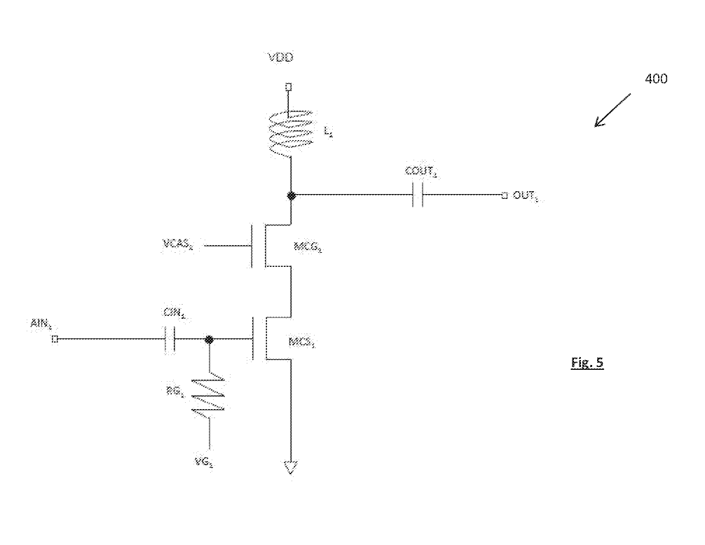

FIG. 5 shows schematic detail of an exemplary LNA 400 which may provide the LNAs in FIGS. 3 and 4, for example. It is not intended to limited the LNAs in FIGS. 3 and 4 to the exemplary circuit of FIG. 5 which is provided by way of example. In the LNA 400 one terminal of a DC blocking capacitor, CIN₁, is connected to the input AIN₁. The other terminal of the DC blocking capacitor, CIN₁, is connected to a gate terminal of a transistor MCS₁. A DC bias voltage source, VG₁, is provided to a gate terminal of the transistor MCS₁ through a resistor RG₁. A source terminal of transistor MCS₁ is connected to GND while a drain terminal of the transistor MCS₁ is connected to a source terminal of a cascode transistor MCG₂. A DC bias level of VCAS₁ is provided at a gate terminal of the transistor MCG₂. The drain terminal of the cascode transistor MCG₂ is connected to one terminal of a inductor L1. The other terminal of the inductor, L₁, is connected to a LNA VDD terminal which supplies current required by the LNA and also provides a DC bias voltage at the drain of the transistor MCG₂. The drain terminal of MCG₂ is also connected to one terminal of an output DC blocking capacitor COUT₁. The other terminal of the DC blocking capacitor COUT₁ is connected to the output port, OUT₁. OMN₁ may be is implemented by appropriately selecting L₁ and COUT₁ to tune the amplifier to operate optimally over its required band of frequencies.

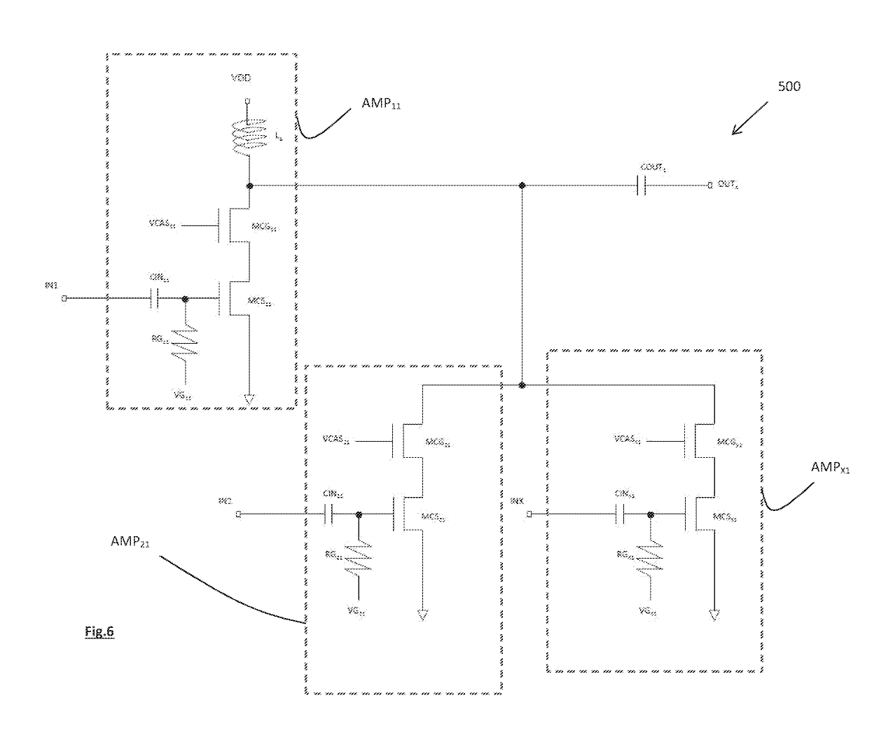

FIG. 6 illustrates three LNAs, AMP₁₁, AMP₂₁, AMP_{X1} sharing output matching network as used in FIGS. 3 and 4. The three LNAs, AMP₁₁, AMP₂₁, AMP_{X1} are identical to the AMP described in FIG. 5 and operate in a similar fashion. In the mode of operation that has previously been described in relation to FIG. 3, the bias voltages VG₁₁, VCAS₁₁ are set to an active on-level so that AMP₁₁ has high gain while the bias voltages VG₂₁, VCAS₂₁, VG_{X1}, VCAS_{X1} are set to an inactive off-level so that AMP₂₁, AMP_{X1} are inactive. OMN₁ is implemented by appropriately selecting L₁ and COUT₁ to tune the amplifier to operate optimally over its required band of frequencies. In this condition an amplified version of signal at IN₁ is output at OUT₁.

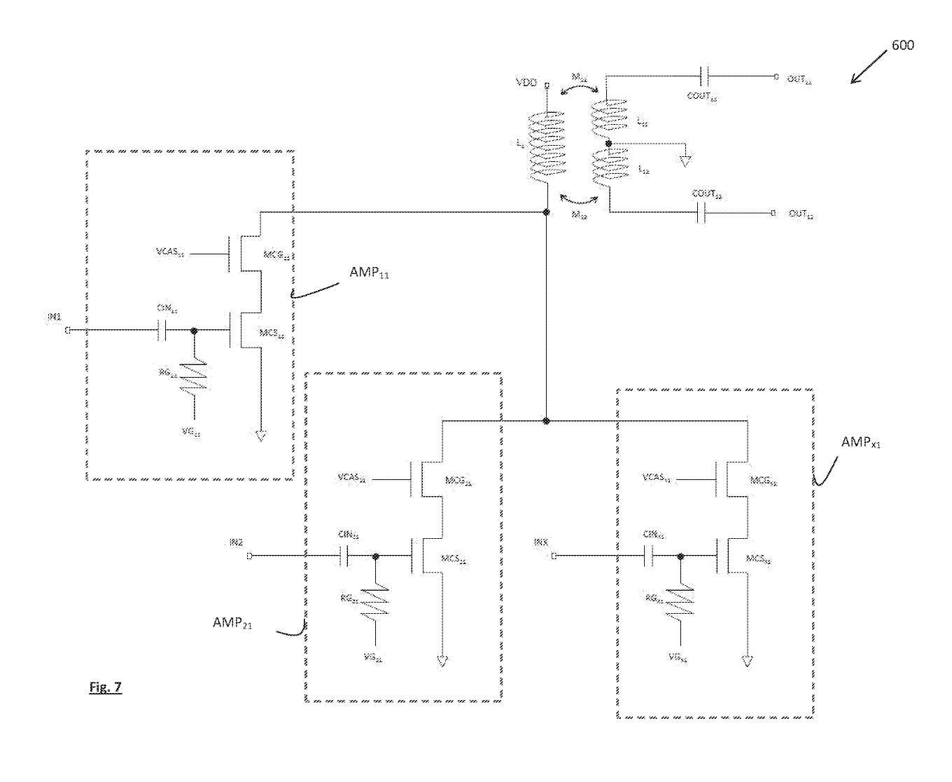

FIG. 7 illustrates three LNAs, AMP₁₁, AMP₂₁, AMP_{X1} sharing output matching network and also including a splitter as used in FIG. 4. In the mode of operation that has previously been described in relation to FIG. 4, the bias voltages VG₁₁, VCAS₁₁ are set to an active on-level so that AMP₁₁ has high gain while the bias voltages VG₂₁, VCAS₂₁, VG_{X1}, VCAS_{X1} are set to an inactive off-level so that AMP₂₁, AMP_{X1} are inactive. OMN₁ is implemented by appropriately selecting L₁, L₁₁, L₁₂, COUT₁₁ and COUT₁₂ to tune the amplifier to operate optimally over its required band of frequencies. Splitter function is implemented by transformer formed by mutual inductance M₁₁ between L₁ and L₁₁, mutual inductance M₁₂ between and L₁ and L₁₂. In this condition an amplified version of signal at IN₁ can be output at both OUT₁₁ and OUT₁₂.

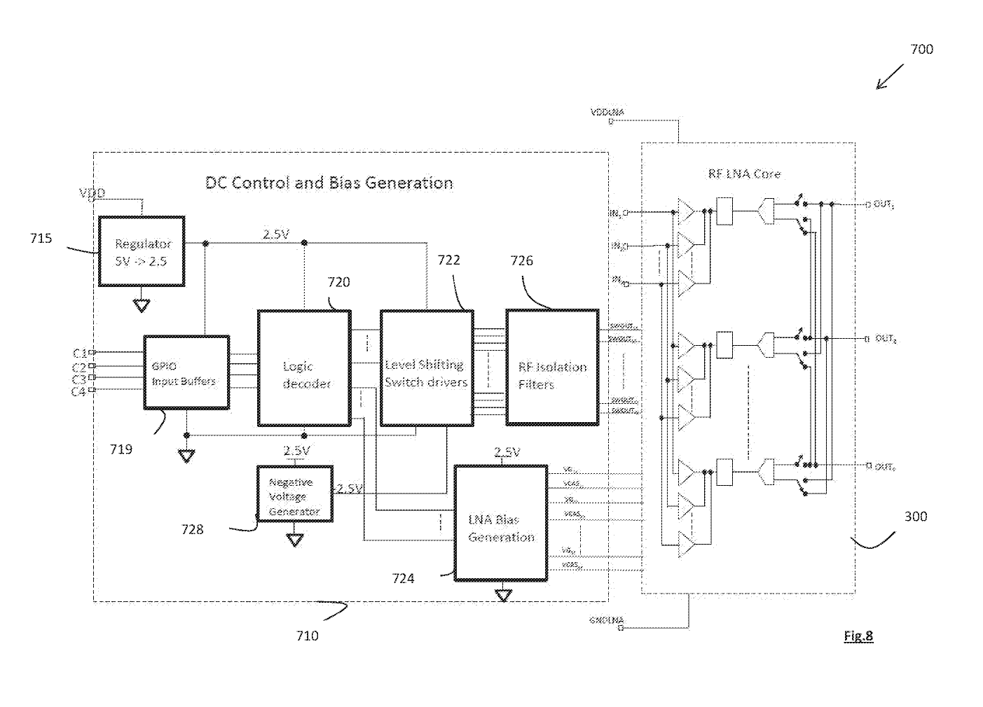

FIG. 8 provide an exemplary RF circuit 700 which incorporates the RF front end circuit 300 of FIG. 4 by way of example. The RF circuit 700 includes two domains; namely, an RF domain section provided by the RF front end circuit 300 and a direct current (DC) domain section 710. The DC domain section 710 may comprise one or more digital logic, bias generation, filter, memory, interface, driver and power management circuitry. In the exemplary RF circuit 700 the DC domain section 710 consists of 5V to 2.5V regulator 715, a negative voltage generator 717, input buffers 719, logic decoder 720, level-shifting switch drivers 722, an LNA bias generator 724, RF isolation filters 726 and a negative voltage generator 728. These circuits are operably configured to generate the required bias levels, provide power management support and control selection through which RF power flows depending on the values set on the control pins C1-C4. In the exemplary embodiment, the LNS bias generator 724 provides a control circuit for selectively activating the amplifiers such that

one or more amplifiers associated with one or more active input nodes are activated while other amplifiers associated with the one or more active input nodes are deactived.

If the RF circuit 700 is configured to operate in the same state as described for FIG. 1 so that amplified version of IN₁ is output at OUT₁ and the amplified version of signal IN₂ is output at both OUT₂ and OUT_{Y}, then the following state is configured by decoder:

| State | VG₁₁ | VCAS₁₁ | VG₂₁ | VCAS₂₁ | VG_{X1} | VCAS_{X1} |
|---|---|---|---|---|---|---|
| 1 | ON | ON | OFF | OFF | OFF | OFF |
| | VG₁₂ | VCAS₁₂ | VG₂₂ | VCAS₂₂ | VG_{X2} | VCAS_{X2} |
| | OFF | OFF | ON | ON | OFF | OFF |
| | VG_{1Y} | VCAS_{1Y} | VG_{2Y} | VCAS_{2Y} | VG_{XY} | VCAS_{XY} |
| | OFF | OFF | ON | ON | OFF | OFF |
| | SWOUT₁₁ | SWOUT₁₂ | SWOUT₂₁ | SWOUT₂₂ | SWOUT_{Y1} | SWOUT_{Y2} |
| | ON | OFF | ON | ON-OUT_{Y} | OFF | OFF |

State 1 is decoded from some logical combination of the control signals received at GPIO inputs, C1-C4. From this table it will be understood that the decoder may have other states so that amplified version of signal at any of three input ports IN₁, IN₂, IN_{X} can be output to any of three output ports, OUT₁, OUT₂, OUT_{Y} by appropriately controlling the bias voltage and switch states.

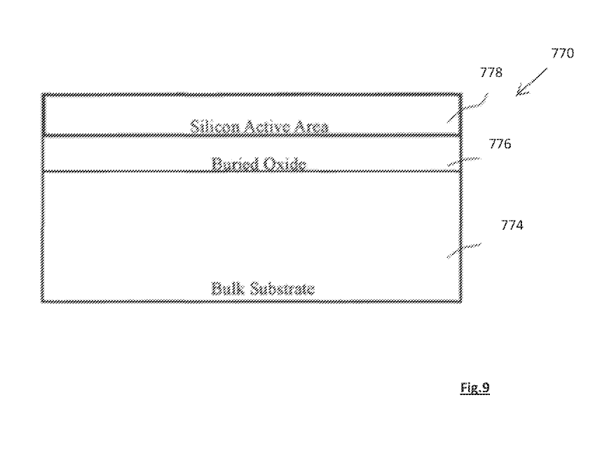

Referring now to FIG. 9 which illustrates a typical silicon-on-insulator (SOI) structure 770 on which the RF circuit 700 may be fabricated thereon. In the exemplary arrangement, an insulating layer sits on top of a silicon substrate. A typical material for the insulating layer is silicon dioxide. In general SOI technologies consist of a bulk substrate 774, a buried oxide layer 776 and a thin active silicon layer 778. The bulk substrate 774 is generally a high resistivity substrate. The bulk substrate 774 can be either P-type or N-Type. A typical thickness for the bulk substrate is 250 μm. The buried oxide layer 776 is an insulator layer, typically silicon dioxide. A typical thickness of the buried oxide layer 776 is 1 μm. The active silicon layer 778 above the buried oxide layer 776 is typically of the order of 0.2 μm. The RF circuit 700 may be fabricated in the silicon active area 778 using semiconductor processing techniques that are well known in the art and may include for example, but not limited to, deposition, implantation, diffusion, patterning, doping, and etching. The RF front end architecture 300 and the DC domain section 710 of the RF circuit 700 are typically fabricated on a single semiconductor structure. However, it is not intended to limit the present teaching to a single semiconductor structure as additional semiconductor structures may be used.

A person of ordinary skill in the art would understand how to fabricate the RF circuit 700 on a substrate using these known techniques. The method may comprise providing a plurality of amplifiers on a substrate defining multiple amplification branches; providing a plurality of input nodes being associated with one or more amplification branches; providing a plurality of output matching networks on the substrate being associated with one or more amplication branches; wherein the amplifiers are selectively controllable such that one or more amplifiers associated with one or more active input nodes are activated while other amplifiers associated with the one or more active input nodes are deactived.

While the present teaching has been described with reference to exemplary arrangements and circuits it will be understood that it is not intended to limit the teaching of the present teaching to such arrangements as modifications can be made without departing from the spirit and scope of the present invention. In this way it will be understood that the present teaching is to be limited only insofar as is deemed necessary in the light of the appended claims. It will be appreciated by those of ordinary skill in the art that a low noise amplifier (LNA) is typically one of the first active elements providing amplification of a signal received at an antenna of a wireless receive system. An LNA is characterised by its noise figure and gain among other parameters. In systems for mobile phone and WiFi applications an LNA is typically required to have a noise figure of less than 1 or 2 dB depending on frequency of operation and gain between 10 and 20 dB within its frequency range of operation. Frequency bands and receive system requirements within those bands are specified by the 3^{rd} Generation Partnership Project, 3GPP consortium for cellular systems. The RF Spectrum is sub-divided into bands which is a range of frequencies within which information must be transmitted or received. Bands that fall within range of 1.8 GHz-2.3 GHz are typically referred to as mid-band frequencies for cellular applications. Bands that fall within range of 2.3-2.7 GHz are typically referred to as high-band frequencies for cellular applications.

Similarly the words comprises/comprising when used in the specification are used to specify the presence of stated features, integers, steps or components but do not preclude the presence or addition of one or more additional features, integers, steps, components or groups thereof.

I claim:

1. An RF front end circuit comprising
a plurality of amplifiers defining multiple amplification branches;
a plurality of input nodes being associated with one or more amplification branches;
a plurality of output matching networks being associated with one or more amplication branches;
wherein the amplifiers are selectively controllable such that one or more amplifiers associated with one or more active input nodes are activated while other amplifiers associated with the one or more active input nodes are deactived.

2. An RF front end circuit of claim 1, wherein by selectively controlling the amplifiers to be active or inactive as required eliminates the need for switches being connected to the inputs of the amplifiers thereby avoiding insertion losses associated with switches contributing to the noise figure of the amplification branches.

3. An RF front end circuit of claim 1; wherein multiple amplifiers are activated that are associated with different active input nodes while other amplifiers associated with the different active input nodes are deactived.

4. An RF front end circuit of claim 1; wherein multiple amplifiers are activated simultaneously that are associated with different active input nodes while other amplifiers associated with the different active input nodes are deactived simultaneously.

5. An RF front end circuit of claim 1, further comprising a control circuit for selectively activating the amplifiers.

6. An RF front end circuit of claim 1; further comprising a plurality of splitters each associated with a corresponding output matching network for splitting the signals from the respective output matching networks into split output signals.

7. An RF front end circuit of claim 6, further comprising an output switching network for selectively switching the split output signals to selected output nodes.

8. An RF front end circuit as claimed in claim 1, wherein each input matching network comprises one or more frequency dependent components.

9. An RF front end circuit as claimed in claim 8, wherein each input matching networks comprises one or more inductive elements.

10. An RF front end circuit as claimed in claim 1, wherein each amplifier comprises an input DC blocking capacitor.

11. An RF front end circuit as claimed in claim 10, wherein each input DC blocking capacitor is operably coupled to a gate of a first transistor.

12. An RF front end circuit as claimed in claim 11, wherein a first DC bias voltage source is operably coupled to the gate of the first transistor via a resistive load.

13. An RF front end circuit as claimed in claim 12, further comprising a cascode transistor operably coupled to the first transistor which together form an amplification stage.

14. An RF front end circuit as claimed in claim 13, wherein a second DC bias voltage source is operably coupled to the gate of the cascode transistor.

15. An RF front end circuit as claimed in claim 13 wherein the cascode transistor is operably coupled to an inductor.

16. An RF front end circuit as claimed in claim 1, further comprising an output DC blocking capacitor operably coupled to the two or more amplifier networks.

17. An RF front end circuit as claim 11, wherein each amplification branch comprises a degeneration inductor operably coupled to the first transistor.

18. An RF front end circuit as claimed in claim 1, wherein the low noise amplifier has a noise figure of less than 1 dB.

19. An RF front end as claimed in claim 1, wherein the low noise amplifier has a noise figure of less than 2 dB.

20. An RF front end as claimed in claim 1, wherein the low noise amplifier is configured to provide a gain of between 10 dB and 20 dB within its frequency range of operation.

21. A semiconductor substrate having an RF front end circuit of claim 1 fabricated thereon.

22. A method of fabricating an RF front end circuit as claimed in claim 1, the method comprising:
providing a plurality of amplifiers on a substrate defining multiple amplification branches;
providing a plurality of input nodes being associated with one or more amplification branches;
providing a plurality of output matching networks on the substrate being associated with one or more amplication branches;
wherein the amplifiers are selectively controllable such that one or more amplifiers associated with one or more active input nodes are activated while other amplifiers associated with the one or more active input nodes are deactived.
